(19) United States
(12) Patent Application Publication
(10) Pub. No.: US 2026/0036151 A1
(43) Pub. Date: Feb. 5, 2026

(54) SPRING CLIP STRUCTURE, CIRCUIT BOARD STRUCTURE AND ELECTRONIC DEVICE

(71) Applicant: Wistron NeWeb Corporation, Hsinchu (TW)

(72) Inventor: Yang Chieh MA, Hsinchu (TW)

(21) Appl. No.: 19/059,404

(22) Filed: Feb. 21, 2025

(30) Foreign Application Priority Data
Jul. 31, 2024 (TW) 113128529

(51) Int. Cl. F16B 2/24; H05K 5/00

(52) U.S. Cl. CPC F16B 2/245; H05K 5/0069; F16B 2200/93

(57) ABSTRACT

A spring clip structure includes an upper plate, a connecting plate and a lower plate. The upper plate includes an upper plate mainbody and a concave arc structure. The concave arc structure is integrally and concavely disposed on the upper plate mainbody. The connecting plate is integrally connected to the upper plate. The lower plate is integrally connected to the connecting plate, and the lower plate includes a lower plate mainbody and a connecting slot. The connecting slot is located on a side of the lower plate mainbody different from the lower plate connecting portion. A clamping space is defined by the upper plate, the connecting plate and the lower plate, the concave arc structure and the lower plate face each other to form a clamping space, and a notch of the connecting slot communicates with the clamping space.

### RELATED APPLICATIONS

This application claims the benefit of priority to Taiwan Patent Application No. 113128529, filed on Jul. 31, 2024. The entire content of the above identified application is incorporated herein by reference.

### BACKGROUND

### Technical Field

The present disclosure relates to a spring clip structure, a circuit board structure, and an electronic device. More particularly, the present disclosure relates to a spring clip structure that can be stably mounted on a circuit board to connect the circuit board and a conductive post, and a circuit board structure and an electronic device including the spring clip structure.

### Description of Related Art

The operation of electronic devices relies on a complete and stable conductive loop, and to ensure stable contact between the circuit board and the conductive post, market-available circuit boards are equipped with compression springs on the circuit board to allow contact between the spring and the conductive copper post, thereby conducting current to the metal conductor on the circuit board.

However, when market-available circuit boards are equipped with springs to connect the conductive post, additional pressure plates or colloid must be configured to compress the spring to contact the conductive post, thus achieving the purpose of current conduction. The additional part configuration increases the preparation cost of the circuit board. Furthermore, the additional parts may cause poor contact due to large size errors of the parts, and too many parts may lead to excessive size chain during assembly, resulting in poor process control, lower yield, and increased production costs.

Therefore, how to provide a clip structure that can be stably mounted on a circuit board, can effectively conduct the circuit, and has an anti-loosening effect has become a goal for research in the related industry.

### SUMMARY

One aspect of the present disclosure provides a spring clip structure including an upper plate, a connecting plate and a lower plate. The upper plate includes an upper plate main body and a concave arc structure. The upper plate main body includes an upper plate connecting portion. The concave arc structure is integrally and concavely disposed on the upper plate main body, and the concave arc structure is located on a side of the upper plate main body different from the upper plate connecting portion. The connecting plate is integrally connected to the upper plate, and the connecting plate is connected to the upper plate connecting portion. The lower plate is integrally connected to the connecting plate, wherein the upper plate and the lower plate are disposed facing each other, and the lower plate includes a lower plate main body and a connecting slot. The lower plate main body includes a lower plate connecting portion, and the lower plate connecting portion is integrally connected to the connecting plate. The connecting slot is located on a side of the lower plate main body different from the lower plate connecting portion. A clamping space is defined by the upper plate, the connecting plate and the lower plate, the concave arc structure is disposed facing the lower plate to form an opening, and a notch of the connecting slot communicates with the opening.

Another aspect of the present disclosure provides a circuit board structure including a circuit board main body and at least two spring clip structures. The at least two spring clip structures are disposed on a surface of the circuit board main body, wherein each of the at least two spring clip structures is configured to clamp a conductive post of an electronic device, and each of the at least two spring clip structures includes an upper plate, a connecting plate and a lower plate. The upper plate includes an upper plate main body and a concave arc structure. The upper plate main body includes an upper plate connecting portion. The concave arc structure is integrally and concavely disposed on the upper plate main body, and the concave arc structure is located on a side of the upper plate main body different from the upper plate connecting portion. The connecting plate is integrally connected to the upper plate, and the connecting plate is connected to the upper plate connecting portion. The lower plate is connected to the circuit board main body, wherein the lower plate is integrally connected to the connecting plate, the upper plate and the lower plate are disposed facing each other, and the lower plate includes a lower plate main body and a connecting slot. The lower plate main body includes a lower plate connecting portion, and the lower plate connecting portion is integrally connected to the connecting plate. The connecting slot is located on a side of the lower plate main body different from the lower plate connecting portion. A clamping space is defined by the upper plate, the connecting plate and the lower plate, the concave arc structure is disposed facing the lower plate to form an opening, and a notch of the connecting slot communicates with the opening.

Yet another aspect of the present disclosure provides an electronic device including a housing, at least two conductive posts and a circuit board structure. The at least two conductive posts are disposed within the housing. The circuit board structure is disposed within the housing and connected to the at least two conductive posts, wherein the circuit board structure includes a circuit board main body and at least two spring clip structures. The at least two spring clip structures are disposed on a surface of the circuit board main body, wherein the at least two spring clip structures are respectively clamped to the at least two conductive posts, and each of the at least two spring clip structures includes an upper plate, a connecting plate and a lower plate. The upper plate includes an upper plate main body and a concave arc structure. The upper plate main body includes an upper plate connecting portion. The concave arc structure is integrally and concavely disposed on the upper plate main body, and the concave arc structure is located on a side of the upper plate main body different from the upper plate connecting portion. The connecting plate is integrally connected to the upper plate, and the connecting plate is connected to the upper plate connecting portion. The lower plate is connected to the circuit board main body, wherein the lower plate is integrally connected to the connecting plate, the upper plate and the lower plate are disposed facing each other, and the lower plate includes a lower plate main body and a connecting slot. The lower plate main body includes a lower plate connecting portion, and the lower plate connecting portion is integrally connected to the connecting plate. The connecting slot is located on a side of the lower plate main body different from the lower plate connecting portion. A clamping space is defined by the upper plate, the connecting plate and the lower plate, the concave arc structure is disposed facing the lower plate to form an opening, and a notch of the connecting slot communicates with the opening.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a spring clip structure in one embodiment of the present disclosure.

FIG. 2 is a side view of the spring clip structure shown in FIG. 1.

FIG. 3 is another schematic diagram of the spring clip structure shown in FIG. 1.

FIG. 4 is a schematic diagram of a circuit board structure in another embodiment of the present disclosure.

FIG. 5 is a schematic diagram of an electronic device in yet another embodiment of the present disclosure.

FIG. 6 is an exploded view of the electronic device shown in FIG. 5.

FIG. 7 is an operational schematic diagram of the circuit board structure in the electronic device shown in FIG. 6 installed on the conductive post.

FIG. 8 is a partially enlarged schematic diagram of the electronic device shown in FIG. 7.

FIG. 9 is a partially enlarged side view of the electronic device shown in FIG. 7.

FIG. 10 is another operational schematic diagram of the circuit board structure in the electronic device shown in FIG. 6 installed on the conductive post.

FIG. 11 is a partially enlarged schematic diagram of the electronic device shown in FIG. 10.

FIG. 12 is a partially enlarged side view of the electronic device shown in FIG. 10.

FIG. 13 is yet another operational schematic diagram of the circuit board structure in the electronic device shown in FIG. 6 installed on the conductive post.

FIG. 14 is a partially enlarged side view of the electronic device shown in FIG. 13.

FIG. 15 is still another operational schematic diagram of the circuit board structure in the electronic device shown in FIG. 6 installed on the conductive post.

FIG. 16 is a partially enlarged side view of the electronic device shown in FIG. 15.

### DETAILED DESCRIPTION

The present disclosure is more particularly described in the following embodiments that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an” and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

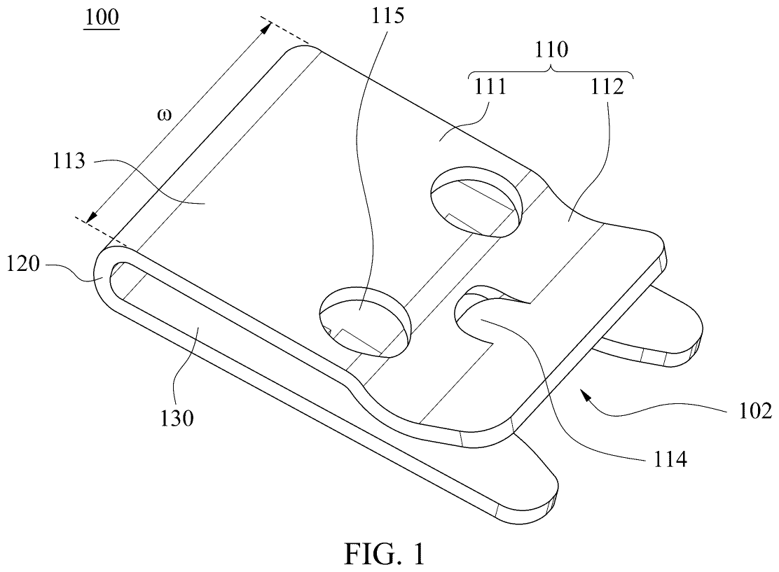

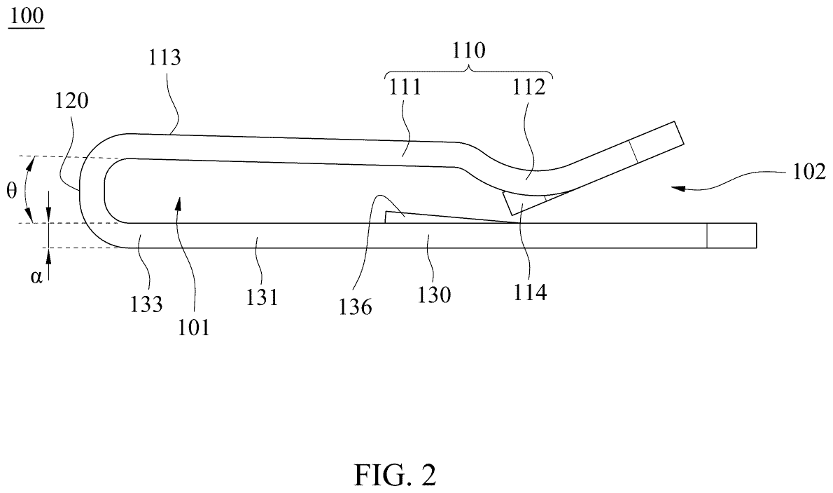

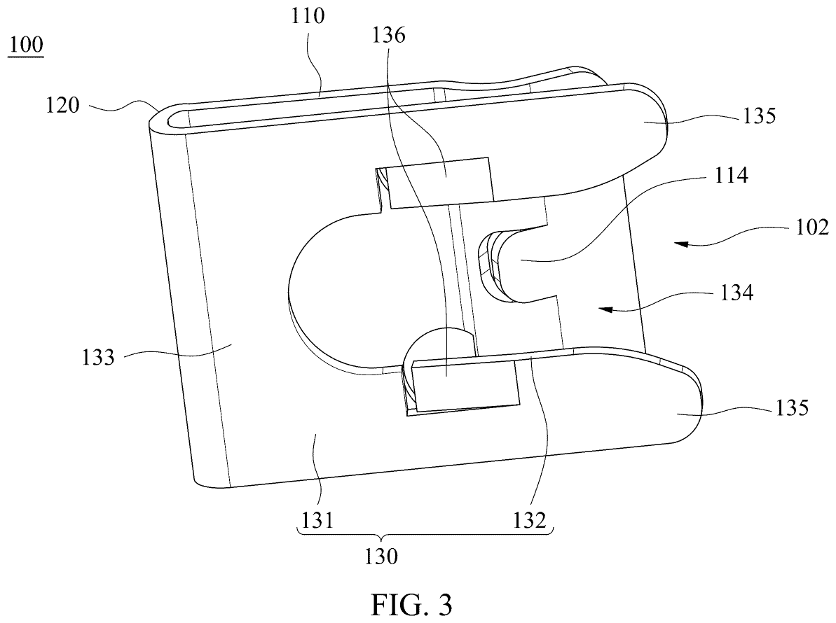

Reference is made to FIG. 1 to FIG. 3, FIG. 1 is a schematic diagram of a spring clip structure 100 in one embodiment of the present disclosure, FIG. 2 is a side view of the spring clip structure 100 shown in FIG. 1, and FIG. 3 is another schematic diagram of the spring clip structure 100 shown in FIG. 1. The spring clip structure 100 includes an upper plate 110, a connecting plate 120 and a lower plate 130.

The upper plate 110 includes an upper plate main body 111 and a concave arc structure 112. The upper plate main body 111 includes an upper plate connecting portion 113. The concave arc structure 112 is integrally and concavely disposed on the upper plate main body 111, and the concave arc structure 112 is located on a side of the upper plate main body 111 different from the upper plate connecting portion 113. Specifically, the concave arc structure 112 is formed by stamping the upper plate 110, making it integrally bent. Further, as shown in FIG. 1 and FIG. 2, the concave arc structure 112 is recessed along a direction toward the lower plate 130, causing the concave arc structure 112 to be disposed facing the lower plate 130 and forming an opening 102 of the spring clip structure 100.

The connecting plate 120 is integrally connected to the upper plate 110, and the connecting plate 120 is connected to the upper plate connecting portion 113. As shown in FIG. 1 and FIG. 2, the connecting plate 120 is a curved sheet having a curvature, the degree of the curvature can be configured according to actual needs, and the present disclosure is not limited to this.

The lower plate 130 is integrally connected to the connecting plate 120. The upper plate 110 and the lower plate 130 are disposed facing each other, and the lower plate 130 includes a lower plate main body 131 and a connecting slot 132. The lower plate main body 131 includes a lower plate connecting portion 133, and the lower plate connecting portion 133 is integrally connected to the connecting plate 120. The connecting slot 132 is located on a side of the lower plate main body 131 different from the lower plate connecting portion 133.

Specifically, the spring clip structure 100 of the present disclosure is formed by stamping an elastic metal spring sheet to integrally bend it, causing the upper plate 110, the connecting plate 120 and the lower plate 130 to connect to each other. Thus, a clamping space 101 of the spring clip structure 100 can be defined by the upper plate 110, the connecting plate 120 and the lower plate 130. The material of the spring clip structure 100 can be beryllium copper, titanium copper, stainless steel, or other metals, and a clamping force of the spring clip structure 100 can be 0.5 N˜2 N.

As shown in FIG. 1 and FIG. 2, the concave arc structure 112 is disposed facing the lower plate 130 to form the opening 102, the lower plate connecting portion 133 and the connecting slot 132 are disposed in pairs on two opposite sides of the lower plate 130, and a notch 134 of the connecting slot 132 faces a direction toward the opening 102, allowing the notch 134 of the connecting slot 132 to communicate with the opening 102. Through the above configuration, when the spring clip structure 100 is to be correspondingly connected to an object (the figure is not shown), the opening 102 of the spring clip structure 100 will face the object, and then the opening 102 of the spring clip structure 100 will abut against the object. At this time, the object is guided by the concave arc structure 112 and the connecting slot 132 to push the upper plate 110 to open the opening 102. Then, the concave arc structure 112 further guides the object to move from the notch 134 into the clamping space 101 and then be positioned in the connecting slot 132, and thus the upper plate 110 and the lower plate 130 will respectively abut against the object so as to achieve the effect of electrical conduction.

Therefore, through the integral connection that the upper plate 110, the connecting plate 120 and the lower plate 130 are integrally connected to each other, the spring clip structure 100 of the present disclosure not only has excellent clamping force and an anti-loosening effect, but also eliminates the need for additional parts to press the spring sheet to conduct electricity. Therefore, the materials and assembly costs of the additional parts can be reduced, the manufacturing process thereof can be effectively shortened, and the impact of tolerance variations on quality can be simultaneously reduced, making the spring clip structure 100 of the present disclosure highly applicable in the market.

As shown in FIG. 1 to FIG. 3, the upper plate 110 can further include a positioning member 114 integrally connected to the concave arc structure 112, and the positioning member 114 protrudes into the clamping space 101. Specifically, the positioning member 114 integrally extends from the concave arc structure 112 and protrudes into the clamping space 101. When the spring clip structure 100 is clamped to the object and correspondingly connected to the object, the positioning member 114 will abut against the object so as to further prevent the object from detaching from the clamping space 101, thereby enhancing the anti-loosening effect of the spring clip structure 100 of the present disclosure.

As shown in FIG. 3, the lower plate 130 can further include two guide plates 135 respectively and integrally connected to the lower plate main body 131, and the two guide plates 135 are connected to the lower plate main body 131 to form the connecting slot 132. Specifically, in the spring clip structure 100, the two guide plates 135 are integrally connected to the lower plate main body 131 to form the connecting slot 132 being fork-shaped. When the spring clip structure 100 is to be correspondingly connected to an object, the object can abut against thereof and enter the connecting slot 132 along the edges of the two guide plates 135, and thus the effect of precise and rapid installation can be achieved. However, it should be noted that the structure of the connecting slot 132 not only can be the fork-shaped structure of FIG. 3, but also can be configured into different shapes such as C-shaped, T-shaped, U-shaped, triangular, etc., depending on the need, and the present disclosure is not limited to the content disclosed in the drawings.

Furthermore, as shown in FIG. 2 and FIG. 3, at least one of the two guide plates 135 can include an abutting member 136, and the abutting member 136 protrudes into the clamping space 101. Specifically, the abutting member 136 integrally extends from the guide plate 135 and protrudes into the clamping space 101. When the spring clip structure 100 is clamped to the object and correspondingly connected to the object, the abutting member 136 will abut against the object and position the object in the connecting slot 132, and thus the anti-loosening effect of the spring clip structure 100 of the present disclosure can be further enhanced. Additionally, in the spring clip structure 100, both of the two guide plates 135 include the abutting members 136, but the present disclosure is not limited to this.

As shown in FIG. 1, the upper plate main body 111 can further include at least one through hole 115, and the at least one through hole 115 is located adjacent to the concave arc structure 112. Through the configuration of the through hole 115, when the spring clip structure 100 is to be correspondingly connected to an object, the user can observe the position of the object in the clamping space 101 through the through hole 115 to confirm whether the spring clip structure 100 is correctly installed, thereby improving the ease of use of the spring clip structure 100 of the present disclosure. Furthermore, in the spring clip structure 100, a number of the through hole 115 is two, but the present disclosure is not limited to this. Additionally, although the through holes 115 are shown as circular in the drawings, the present disclosure is not limited to this shape.

As shown in FIG. 1 and FIG. 2, a thickness of the lower plate 130 is a, and the following condition can be satisfied: 0.08 mm≤α≤0.15 mm. Thus, the spring clip structure 100 has excellent rebounding reset force to prevent the spring clip structure 100 from loosening, and it has a superior circuit conduction effect.

Furthermore, an angle between the upper plate 110 and the lower plate 130 is θ, a width of the spring clip structure 100 is ω, and the following conditions can be satisfied: 1°≤θ≤5°; or 1.5 mm≤ω≤2.5 mm. When the angle θ between the upper plate 110 and the lower plate 130 or the width ω of the spring clip structure 100 satisfies the above conditions, an appropriate installation force can be achieved, and the clamping force of the spring clip structure 100 can be effectively maintained. Therefore, it is favorable for meeting the market usage specifications under the premise of appropriate installation force, thereby reducing the assembly difficulty of the spring clip structure 100. Additionally, in the spring clip structure 100, a distance between the upper plate 110 and the lower plate 130 on a side close to the connecting plate 120 (or a maximum height of the connecting plate 120) can be 1.0 mm to 2.0 mm, and the distance as mentioned must be greater than the distance between the concave arc structure 112 and the lower plate 130, but the present disclosure is not limited to this.

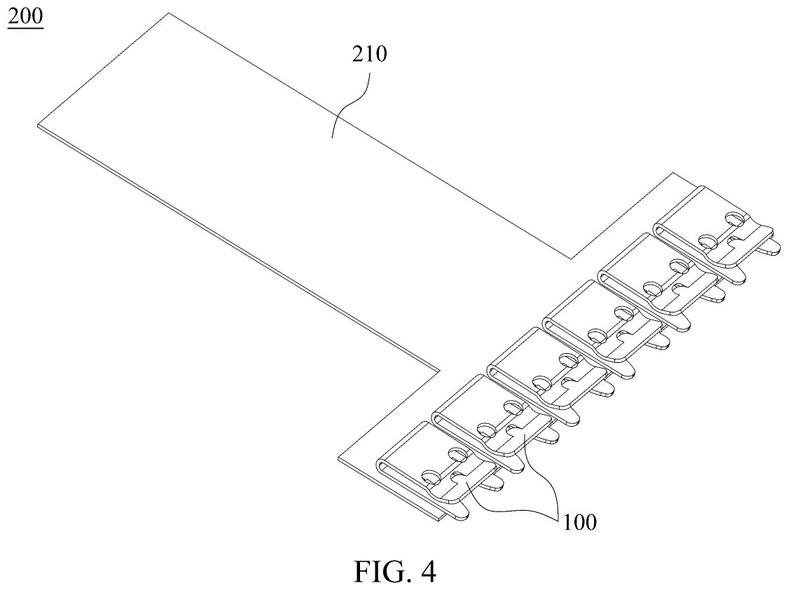

Reference is made to FIG. 4, which is a schematic diagram of a circuit board structure 200 in another embodiment of the present disclosure. The circuit board structure 200 includes a circuit board main body 210 and at least two spring clip structures 100.

In the circuit board structure 200, the circuit board main body 210 can be a commercially available rigid printed circuit board (RPCB) or a flexible printed circuit board (FPC), and the at least two spring clip structures 100 are disposed on a surface (reference number is omitted) of the circuit board main body 210, wherein each of the at least two spring clip structures 100 is configured to clamp a conductive post (figure is not shown) of an electronic device.

Specifically, the spring clip structure 100 of the circuit board structure 200 is the same as the spring clip structure 100 shown in FIG. 1 to FIG. 3. Please refer to the description of FIG. 1 to FIG. 3 for the same details, which will not be repeated here. As shown in FIG. 4, both of two spring clip structures 100 of the circuit board structure 200 can be located on the same surface of the circuit board main body 210 to facilitate subsequent connections with the conductive posts of the electronic device. The spring clip structures 100 can be directly mounted on the surface of the circuit board main body 210 using the surface mount technology (SMT), thereby eliminating the need for additional assembly components that are typically required when installing springs on the circuit board main body 210, and the need for rework time and costs associated with removing fixing glue and dismantling fixing components in conventional techniques during the manufacturing process can be avoided. As a result, the manufacturing cost of the circuit board structure 200 of the present disclosure can be significantly reduced, and it has excellent market application potential.

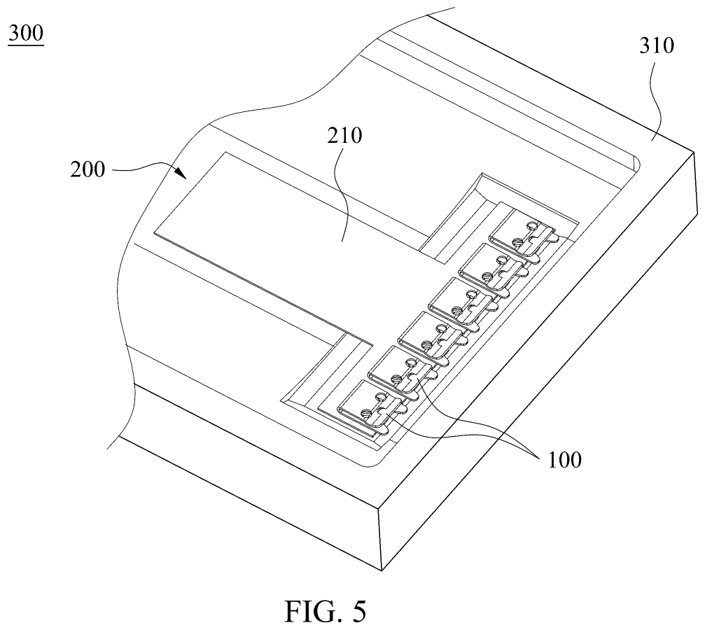

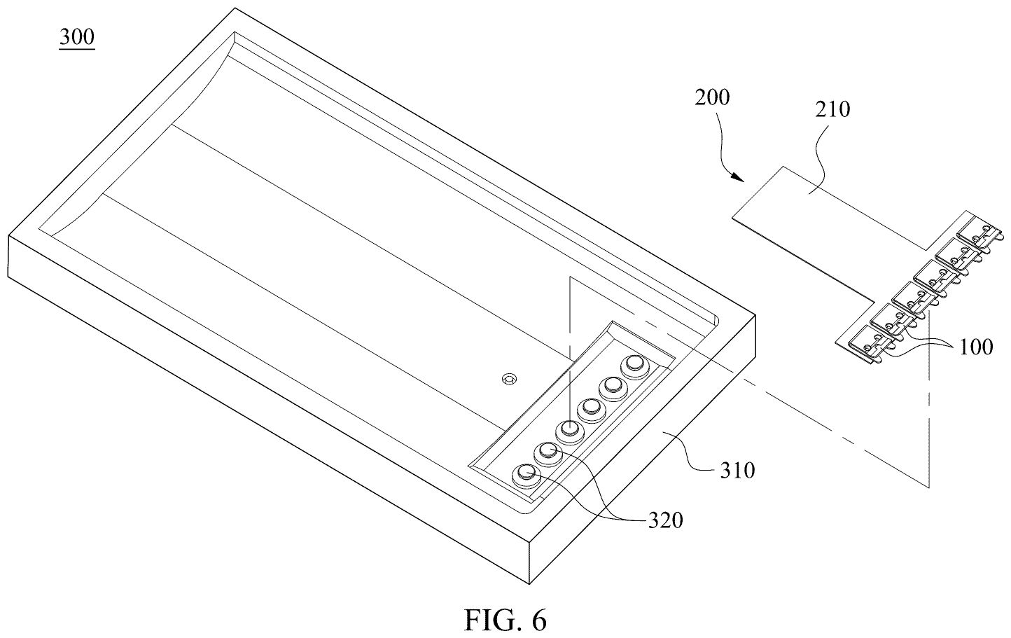

Reference is made to FIG. 5 and FIG. 6, FIG. 5 is a schematic diagram of an electronic device 300 in another embodiment of the present disclosure, and FIG. 6 is an exploded view of the electronic device 300 shown in FIG. 5. The electronic device 300 includes a housing 310, at least two conductive posts 320 and a circuit board structure 200.

The at least two conductive posts 320 are disposed within the housing 310. The circuit board structure 200 is disposed within the housing 310 and connected to the at least two conductive posts 320. The circuit board structure 200 includes a circuit board main body 210 and at least two spring clip structures 100, so that the spring clip structures 100 of the circuit board structure 200 are clamped onto the conductive posts 320 to achieve electrical connection. Additionally, in the electronic device 300, the spring clip structure 100 is the same as the spring clip structure 100 shown in FIG. 1 to FIG. 3, and the circuit board structure 200 is the same as the circuit board structure 200 shown in FIG. 4. Therefore, for the same details, please refer to the descriptions of FIG. 1 to FIG. 4, which will not be repeated here.

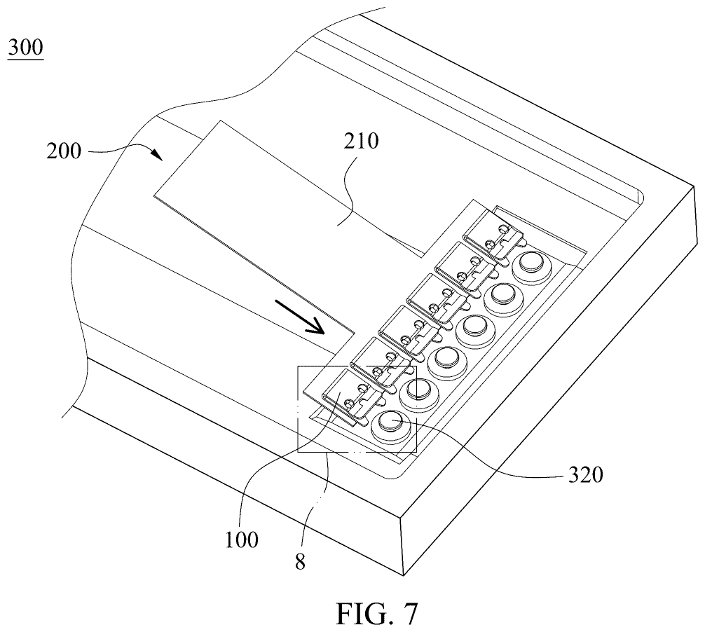

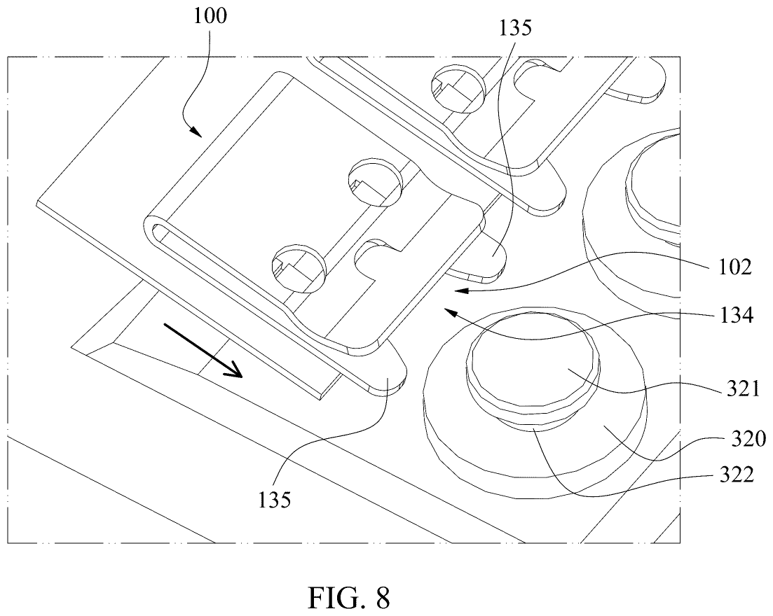

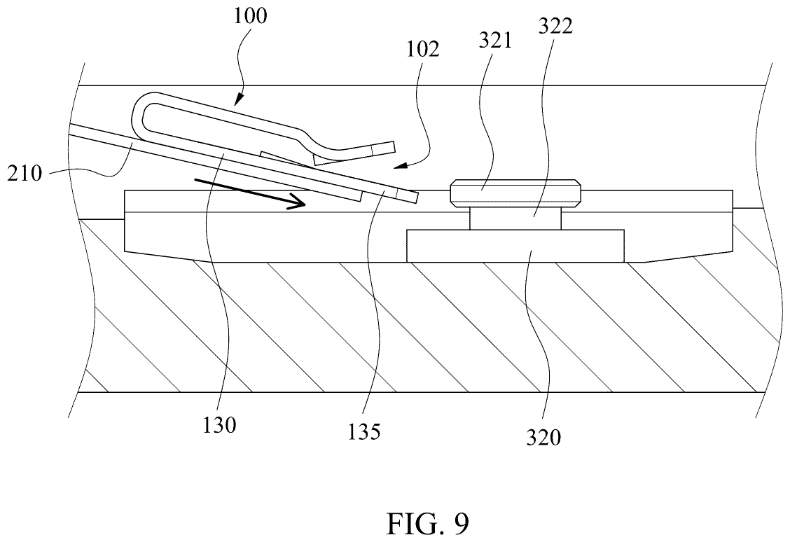

The installation details of the circuit board structure 200 and the conductive posts 320 in the electronic device 300 will be described below with the reference of FIG. 7 to FIG. 16. Reference is made to FIG. 7 to FIG. 9 in advance. FIG. 7 is a first operational schematic diagram of the circuit board structure 200 in the electronic device 300 shown in FIG. 6 being installed on the conductive posts 320, FIG. 8 is a partially enlarged schematic diagram of the electronic device 300 shown in FIG. 7, and FIG. 9 is a partially enlarged side view of the electronic device 300 shown in FIG. 7.

As shown in FIG. 7 to FIG. 9, when the circuit board structure 200 is to be installed within the housing 310 and connected to the conductive posts 320, the orientation of the circuit board structure 200 is adjusted so that the circuit board main body 210 approaches the conductive posts 320, causing the opening 102 of the spring clip structure 100 to face the conductive posts 320 and align with a head 321 of the conductive posts 320. At this time, the connecting slot 132 (as shown in FIG. 3) of the lower plate 130 of the spring clip structure 100 will align with a neck 322 of the conductive posts 320 by the notch 134 thereof, and the two guide plates 135 will respectively align with the two opposite sides of the neck 322 of the conductive posts 320.

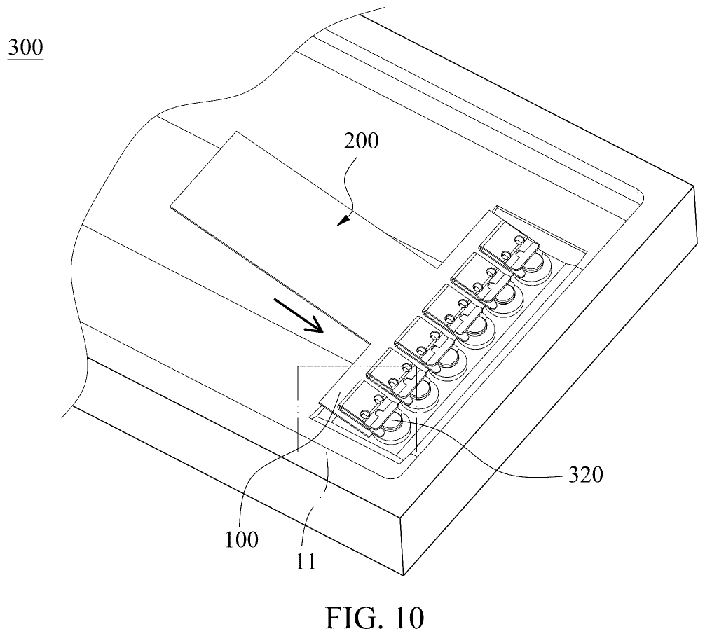

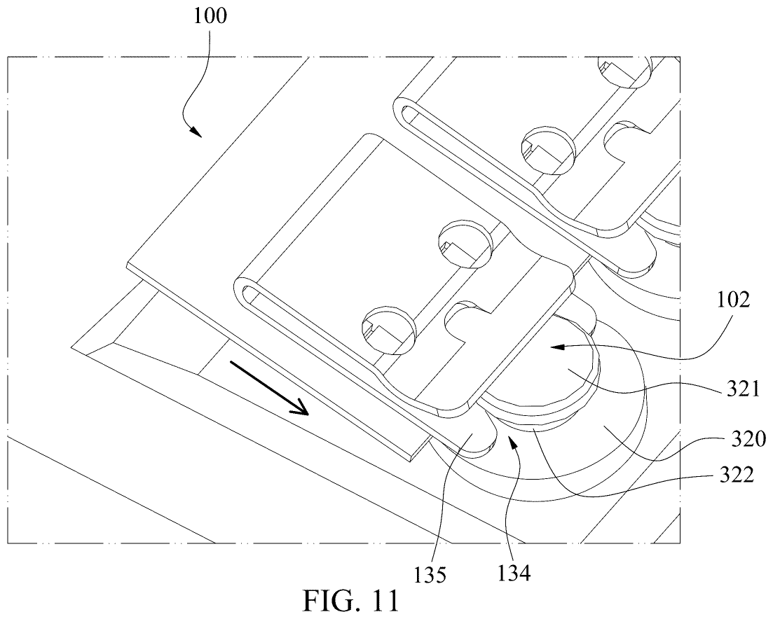

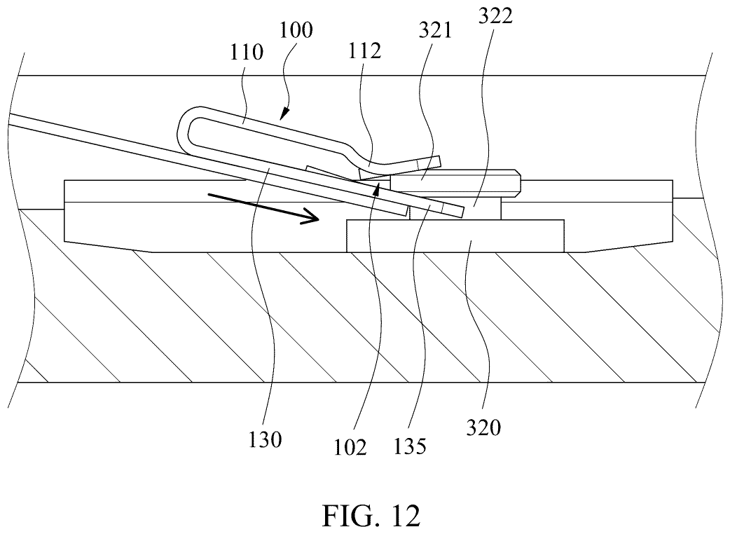

Reference is made to FIG. 10 to FIG. 12, FIG. 10 is another operational schematic diagram of the circuit board structure 200 in the electronic device 300 shown in FIG. 6 being installed on the conductive posts 320, FIG. 11 is a partially enlarged schematic diagram of the electronic device 300 shown in FIG. 10, and FIG. 12 is a partially enlarged side view of the electronic device 300 shown in FIG. 10.

As shown in FIG. 10 to FIG. 12, when the circuit board structure 200 continues to be pushed toward the conductive posts 320 along the direction of the arrow, the head 321 of the conductive posts 320 abut against the upper plate 110 and the lower plate 130 of the spring clip structure 100. The concave arc structure 112 of the upper plate 110 abuts against an edge of the head 321, causing the conductive posts 320 to be engaged by the opening 102 of the spring clip structure 100 and positioned in the notch 134 of the connecting slot 132. At the same time, the two guide plates 135 of the lower plate 130 respectively abut against the two sides of the neck 322 of the conductive posts 320, guiding the installation direction of the conductive posts 320.

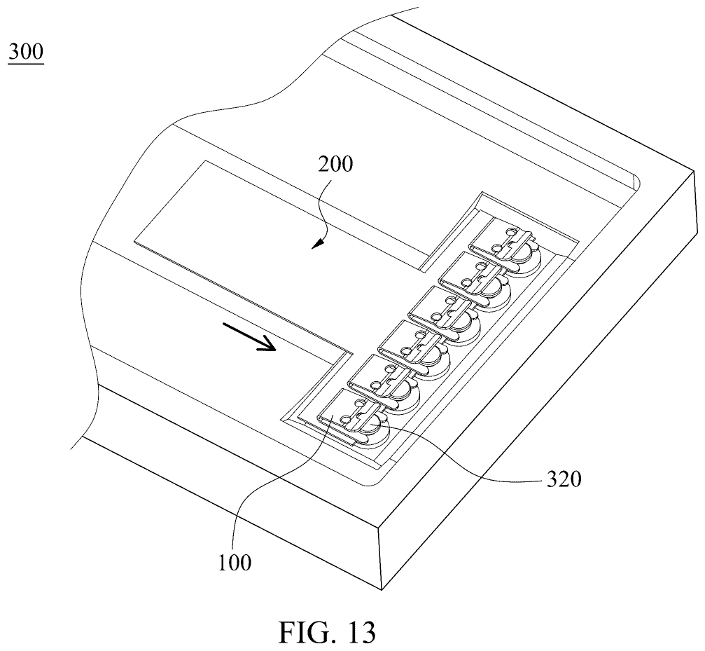

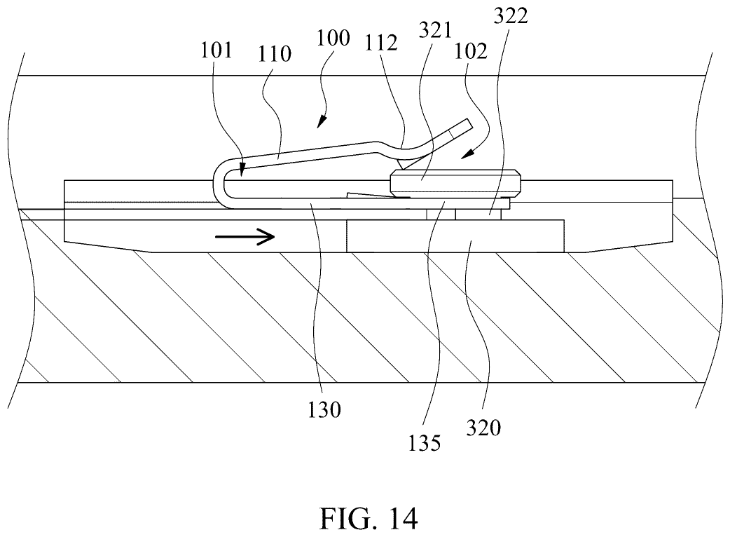

Reference is made to FIG. 13 and FIG. 14, FIG. 13 is yet another operational schematic diagram of the circuit board structure 200 in the electronic device 300 shown in FIG. 6 being installed on the conductive posts 320, and FIG. 14 is a partially enlarged side view of the electronic device 300 shown in FIG. 13.

As shown in FIG. 13 and FIG. 14, when the circuit board structure 200 continues to be pushed toward the conductive posts 320 along the direction of the arrow, the spring clip structure 100 will elastically deform due to the abutment of the conductive posts 320, causing the concave arc structure 112 of the upper plate 110 to move and abut against the top surface (reference number is omitted) of the head 321 of the conductive posts 320. At this time, the conductive posts 320 are guided by the two guide plates 135 to enter the clamping space 101 of the spring clip structure 100 through the opening 102, and thus the neck 322 thereof is positioned in the connecting slot 132.

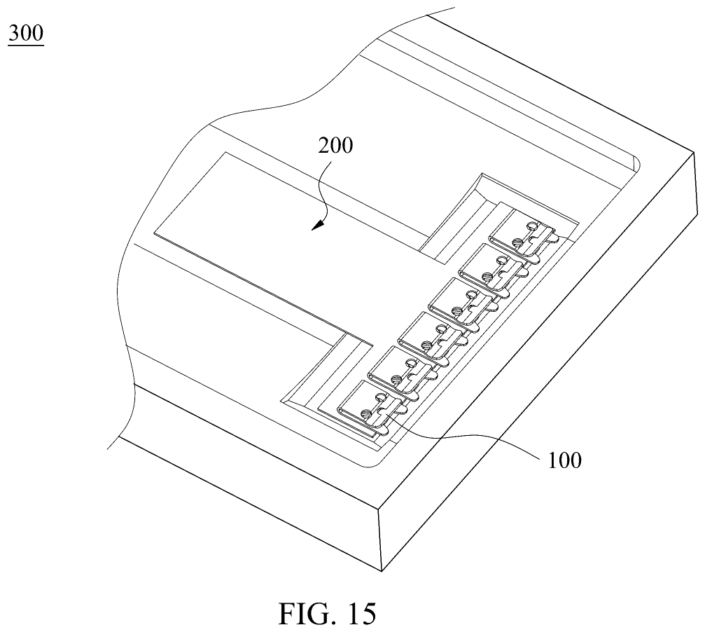

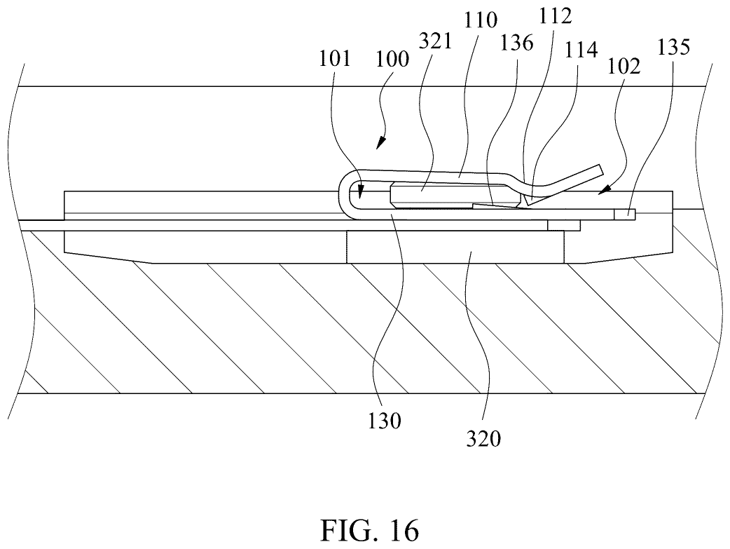

Reference is made to FIG. 15 and FIG. 16. FIG. 15 is still another operational schematic diagram of the circuit board structure 200 in the electronic device 300 shown in FIG. 6 being installed on the conductive posts 320, and FIG. 16 is a partially enlarged side view of the electronic device 300 shown in FIG. 15.

As shown in FIG. 15 and FIG. 16, when the circuit board structure 200 continues to be pushed toward the conductive posts 320 along the direction of the arrow, and the conductive posts 320 are fully inserted into the clamping space 101 of the spring clip structure 100, the opening 102 of the spring clip structure 100 is closed. At this time, the conductive posts 320 are clamped and positioned in the clamping space 101 by the upper plate 110 and the lower plate 130, causing the head 321 of the conductive posts 320 to abut against the upper plate 110 and the lower plate 130 to abut against both the head 321 and the neck 322 of the conductive posts 320 (as shown in FIG. 14), so the effect of electrical contact can be achieved. At the same time, the positioning member 114, which integrally extends from the concave arc structure 112 and protrudes into the clamping space 101, will abut against the head 321 of the conductive posts 320, and the conductive posts 320 can be prevented from detaching from the clamping space 101. Additionally, the abutting member 136 of the guide plate 135, which protrudes into the clamping space 101, will abut against another side of the head 321 of the conductive posts 320 so as to position the neck 322 of the conductive posts 320 in the connecting slot 132.

Therefore, by the arrangement that the circuit board structure 200 includes at least two spring clip structures 100, and the spring clip structure 100 is integrally formed by the upper plate 110, connecting plate 120 and lower plate 130, the electronic device 300 of the present disclosure not only provides a superior clamping force and an anti-loosening effect, but also eliminates the need for additional components to press the spring sheet for conduction, thereby effectively reducing the material and assembly costs of additional components, shortening the manufacturing process of the spring clip structure 100 and the assembly complexity of the electronic device 300, and reducing the impact of tolerance variations on quality. Thus, the electronic device 300 of the present disclosure has superior market application potential.

### EXAMPLE

The following will analyze the clamping force strength of the spring clip structure in the circuit board structure of the present disclosure during installation, along with the corresponding parameter values. The spring clip structure used in this example can be the spring clip structure 100 shown in FIG. 1 to FIG. 3. Please refer to the description of FIG. 1 to FIG. 3 for the same details, which will not be repeated here.

In this example, a number of the spring clip structure is 6, and the material of the spring clip structure is beryllium copper. The thickness a of the lower plate is selected as 0.1 mm and 0.12 mm, the width w of the spring clip structure is selected as 2.0 mm and 2.2 mm, and the angle θ between the upper plate and the lower plate is selected as 1.5° and 2.5° for testing. The corresponding clamping force values are listed in Table 1.

TABLE 1

| | | | | | Clamping |
|---|---|---|---|---|---|
| | | | | Clamping | Force/ |
| | α | ω | θ | Force | Unit |
| Group | (mm) | (mm) | (°) | (6 units) | (N) |
| 1 | 0.1 | 2.0 | 1.5 | 0.654 kgf/6.413N | 1.068N |
| 2 | 0.1 | 2.2 | 1.5 | 0.893 kgf/8.757N | 1.460N |
| 3 | 0.1 | 2.0 | 2.5 | 0.722 kgf/7.080N | 1.180N |
| 4 | 0.1 | 2.2 | 2.5 | 0.936 kgf/9.179N | 1.530N |
| 5 | 0.12 | 2.0 | 1.5 | 1.193 kgf/11.699N | 1.950N |

As shown in Table 1, when the thickness a of the lower plate satisfies the range of 0.08 mm to 0.15 mm, the width w of the spring clip structure satisfies the range of 1.5 mm to 2.5 mm, or the angle θ between the upper plate and the lower plate satisfies the range of 1° to 5°, the clamping force of each of the spring clip structures can be 0.5 N to 2 N. Therefore, the spring clip structure of the present disclosure has appropriate installation force, the assembly difficulty of the spring clip structure 100 can be effectively reduced, and the market specifications of the circuit board structure and the electronic device including the spring clip structure of the present disclosure can be achieved, providing superior market application potential.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A spring clip structure, comprising:
an upper plate, comprising:
an upper plate main body comprising an upper plate connecting portion; and
a concave arc structure integrally and concavely disposed on the upper plate main body, and the concave arc structure located on a side of the upper plate main body different from the upper plate connecting portion;
a connecting plate integrally connected to the upper plate, and the connecting plate connected to the upper plate connecting portion; and
a lower plate integrally connected to the connecting plate, wherein the upper plate and the lower plate are disposed facing each other, and the lower plate comprises:
a lower plate main body comprising a lower plate connecting portion, and the lower plate connecting portion integrally connected to the connecting plate; and
a connecting slot located on a side of the lower plate main body different from the lower plate connecting portion;
wherein a clamping space is defined by the upper plate, the connecting plate and the lower plate, the concave arc structure is disposed facing the lower plate to form an opening, and a notch of the connecting slot communicates with the opening.

2. The spring clip structure of claim 1, wherein the upper plate further comprises:
a positioning member integrally connected to the concave arc structure, and the positioning member protruding into the clamping space.

3. The spring clip structure of claim 1, wherein the lower plate further comprises:
two guide plates respectively and integrally connected to the lower plate main body, and the two guide plates connected to the lower plate main body to form the connecting slot.

4. The spring clip structure of claim 3, wherein at least one of the two guide plates comprises an abutting member, and the abutting member protrudes into the clamping space.

5. The spring clip structure of claim 1, wherein a clamping force of the spring clip structure is 0.5 N˜2 N.

6. The spring clip structure of claim 5, wherein a thickness of the lower plate is a, and the following condition is satisfied:
$$0.08 mm \leq α \leq 0.15 mm .$$

7. The spring clip structure of claim 5, wherein an angle between the upper plate and the lower plate is θ, a width of the spring clip structure is ω, and the following condition is satisfied:
$$1 ° \leq θ \leq 5 ° ; or$$
$$1.5 mm \leq ω \leq 2.5 mm .$$

8. The spring clip structure of claim 1, wherein the upper plate main body further comprises:
at least one through hole located adjacent to the concave arc structure.

9. A circuit board structure, comprising:
a circuit board main body; and
at least two spring clip structures disposed on a surface of the circuit board main body, wherein each of the at least two spring clip structures is configured to clamp a conductive post of an electronic device, and each of the at least two spring clip structures comprises:
an upper plate, comprising:
an upper plate main body comprising an upper plate connecting portion; and
a concave arc structure integrally and concavely disposed on the upper plate main body, and the concave arc structure located on a side of the upper plate main body different from the upper plate connecting portion;
a connecting plate integrally connected to the upper plate, and the connecting plate connected to the upper plate connecting portion; and
a lower plate connected to the circuit board main body, wherein the lower plate is integrally connected to the connecting plate, the upper plate and the lower plate are disposed facing each other, and the lower plate comprises:
a lower plate main body comprising a lower plate connecting portion, and the lower plate connecting portion integrally connected to the connecting plate; and
a connecting slot located on a side of the lower plate main body different from the lower plate connecting portion;
wherein a clamping space is defined by the upper plate, the connecting plate and the lower plate, the concave arc structure is disposed facing the lower plate to form an opening, and a notch of the connecting slot communicates with the opening.

10. The circuit board structure of claim 9, wherein the upper plate further comprises:
a positioning member integrally connected to the concave arc structure, and the positioning member protruding into the clamping space.

11. The circuit board structure of claim 9, wherein the lower plate further comprises:
two guide plates respectively and integrally connected to the lower plate main body, and the two guide plates connected to the lower plate main body to form the connecting slot.

12. The circuit board structure of claim 11, wherein at least one of the two guide plates comprises an abutting member, and the abutting member protrudes into the clamping space.

13. The circuit board structure of claim 9, wherein a clamping force of the spring clip structure is 0.5 N˜2 N.

14. The circuit board structure of claim 13, wherein a thickness of the lower plate is α, and the following condition is satisfied:
$$0.08 mm \leq α \leq 0.15 mm .$$

15. The circuit board structure of claim 13, wherein an angle between the upper plate and the lower plate is θ, a width of the spring clip structure is ω, and the following condition is satisfied:
$$1 ° \leq θ \leq 5 ° ; or$$
$$1.5 mm \leq ω \leq 2.5 mm .$$

16. The circuit board structure of claim 9, wherein the upper plate main body further comprises:
at least one through hole located adjacent to the concave arc structure.

17. An electronic device, comprising:
a housing;
at least two conductive posts disposed within the housing; and
a circuit board structure disposed within the housing and connected to the at least two conductive posts, wherein the circuit board structure comprises:
a circuit board main body; and
at least two spring clip structures disposed on a surface of the circuit board main body, wherein the at least two spring clip structures are respectively clamped onto the at least two conductive posts, and each of the at least two spring clip structures comprises:
an upper plate, comprising:
an upper plate main body comprising an upper plate connecting portion; and
a concave arc structure integrally and concavely disposed on the upper plate main body, and the concave arc structure located on a side of the upper plate main body different from the upper plate connecting portion;
a connecting plate integrally connected to the upper plate, and the connecting plate connected to the upper plate connecting portion; and
a lower plate connected to the circuit board main body, wherein the lower plate is integrally connected to the connecting plate, the upper plate and the lower plate are disposed facing each other, and the lower plate comprises:
a lower plate main body comprising a lower plate connecting portion, the lower plate connecting portion integrally connected to the connecting plate; and
a connecting slot located on a side of the lower plate main body different from the lower plate connecting portion;
wherein a clamping space is defined by the upper plate, the connecting plate and the lower plate, the concave arc structure is disposed facing the lower plate to form an opening, and a notch of the connecting slot communicates with the opening.

18. The electronic device of claim 17, wherein the upper plate further comprises:
a positioning member integrally connected to the concave arc structure, and the positioning member protruding into the clamping space.

19. The electronic device of claim 17, wherein the lower plate further comprises:
two guide plates respectively and integrally connected to the lower plate main body, and the two guide plates connected to the lower plate main body to form the connecting slot.

20. The electronic device of claim 19, wherein at least one of the two guide plates comprises an abutting member, and the abutting member protrudes into the clamping space.

21. The electronic device of claim 17, wherein a clamping force of the spring clip structure is 0.5 N˜2 N.

22. The electronic device of claim 21, wherein a thickness of the lower plate is α, and the following condition is satisfied:
$$0.08 mm \leq α \leq 0.15 mm .$$

23. The electronic device of claim 21, wherein an angle between the upper plate and the lower plate is θ, a width of the spring clip structure is ω, and the following condition is satisfied:
$$1 ° \leq θ \leq 5 ° ; or$$
$$1.5 mm \leq ω \leq 2.5 mm .$$

24. The electronic device of claim 17, wherein the upper plate main body further comprises:
at least one through hole located adjacent to the concave arc structure.
